(19) United States
(12) Patent Application Publication
(10) Pub. No.: US 2023/0160646 A1
(43) Pub. Date: May 25, 2023

(54) IMMERSION HEAT DISSIPATION STRUCTURE

(71) Applicant: AMULAIRE THERMAL TECHNOLOGY, INC., New Taipei City (TW)

(72) Inventors: CHING-MING YANG, New Taipei City (TW); CHENG-SHU PENG, New Taipei City (TW); TZE-YANG YEH, New Taipei City (TW)

(21) Appl. No.: 17/530,466

(22) Filed: Nov. 19, 2021

(51) Int. Cl. F28F 13/00; H05K 7/20; F28F 21/08

(52) U.S. Cl. CPC F28F 13/003; H05K 7/20254; F28F 21/081; H05K 7/20236; F28F 2013/005; F28F 2255/00

(57) ABSTRACT

An immersion heat dissipation structure is provided. The immersion heat dissipation structure includes a porous metal heat dissipation material, an integrated heat spreader, and a thermal interface material. The porous metal heat dissipation material has a porosity greater than 8%. The porous metal heat dissipation material and the integrated heat spreader have the thermal interface material arranged therebetween so that a thermal connection is formed therebetween. A connection surface of the porous metal heat dissipation material and a connection surface of the thermal interface material have a sealing layer or a sealing material arranged therebetween.

### FIELD OF THE DISCLOSURE

The present disclosure relates to a heat dissipation structure, and more particularly to an immersion heat dissipation structure.

### BACKGROUND OF THE DISCLOSURE

An immersion cooling technology is performed by directly immersing heat-generating components (such as servers and disk arrays) in a cooling fluid that is non-electrically conductive, so that heat generated by operations of the heat-generating components can be removed by evaporation of the cooling fluid. However, how heat can be more effectively dissipated through the immersion cooling technology is still one of the issues that needs to be solved in the related field.

### SUMMARY OF THE DISCLOSURE

In response to the above-referenced technical inadequacy, the present disclosure provides an immersion heat dissipation structure.

In one aspect, the present disclosure provides an immersion heat dissipation structure, which includes a porous metal heat dissipation material, an integrated heat spreader, and a thermal interface material. The porous metal heat dissipation material has a porosity greater than 8%. The porous metal heat dissipation material and the integrated heat spreader have the thermal interface material arranged therebetween so that a thermal connection is formed therebetween, and a connection surface of the porous metal heat dissipation material and a connection surface of the thermal interface material have a sealing layer arranged therebetween. The sealing layer seals a plurality of open pores formed on the connection surface of the porous metal heat dissipation material, and a thickness of the sealing layer is less than 0.1 mm.

In certain embodiments, the sealing layer is a film layer formed by one of a steaming process, blocking with an organosilicon compound, filling with a passivation solution, blocking with an immobilization material, a physical vapor deposition process, or a chemical vapor deposition process.

In certain embodiments, the thermal interface material is made of silicone grease, silica gel, epoxy resin, or metal.

In another aspect, the present disclosure provides an immersion heat dissipation structure, which includes a porous metal heat dissipation material, an integrated heat spreader, and a thermal interface material. The porous metal heat dissipation material has a porosity greater than 8%. The porous metal heat dissipation material and the integrated heat spreader have the thermal interface material arranged therebetween so that a thermal connection is formed therebetween. A plurality of open pores are formed on a connection surface of the porous metal heat dissipation material, and at least one of the plurality of open pores is filled with a sealing material to fill at least a part of the at least one of the plurality of open pores.

In certain embodiments, the sealing material is formed by forming a sealing layer on the connection surface of the porous metal heat dissipation material, and filling the sealing material forming the sealing layer into the at least one of the plurality of open pores.

In certain embodiments, the sealing material is formed by forming a sealing layer on the connection surface of the porous metal heat dissipation material, removing the sealing layer by a chemical process or a mechanical process, and leaving a remaining part of the sealing material of the sealing layer in the open pore.

In yet another aspect, the present disclosure provides an immersion heat dissipation structure, which includes a porous metal heat dissipation material, an integrated heat spreader, and a thermal interface material. The porous metal heat dissipation material has a porosity greater than 8%. The porous metal heat dissipation material and the integrated heat spreader have the thermal interface material arranged therebetween so that a thermal connection is formed therebetween. A connection surface of the porous metal heat dissipation material is a processed surface having a porosity less than 8% that is formed by processing.

In certain embodiments, the connection surface of the porous metal heat dissipation material is the processed surface having the porosity less than 8% that is formed by sandblasting, grinding, or polishing.

In certain embodiments, the connection surface of the porous metal heat dissipation material is the processed surface having the porosity less than 8% that is formed by chemical etching or acid etching.

Therefore, in the immersion heat dissipation structure provided by the present disclosure, by virtue of “the porous metal heat dissipation material having the porosity greater than 8%”, “the porous metal heat dissipation material and the integrated heat spreader having the thermal interface material arranged therebetween so that the thermal connection is formed therebetween”, “the connection surface of the porous metal heat dissipation material and the connection surface of the thermal interface material having the sealing layer arranged therebetween, the sealing layer sealing the plurality of open pores formed on the connection surface of the porous metal heat dissipation material and the thickness of the sealing layer being less than 0.1 mm”, “the at least one of the plurality of open pores formed on the connection surface of the porous metal heat dissipation material being filled with the sealing material to fill at least a part of the at least one of the plurality of open pores”, or “the connection surface of the porous metal heat dissipation material being the processed surface having the porosity less than 8% that is formed by processing,” an air bubble generation in an area of the porous metal heat dissipation material of the immersion heat dissipation structure provided by the embodiments of the present disclosure can be effectively increased, and the connection property and the thermal conductivity between the thermal interface material and the porous metal heat dissipation material can be effectively increased, thereby further improving the thermal transmittance of the immersion heat dissipation structure.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of an immersion heat dissipation structure according to a first embodiment of the present disclosure;

FIG. 2 is a schematic side view of an immersion heat dissipation structure according to a second embodiment of the present disclosure;

FIG. 3 is a schematic side view of an immersion heat dissipation structure according to a third embodiment of the present disclosure; and

FIG. 4 is a schematic side view of an immersion heat dissipation structure according to a fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

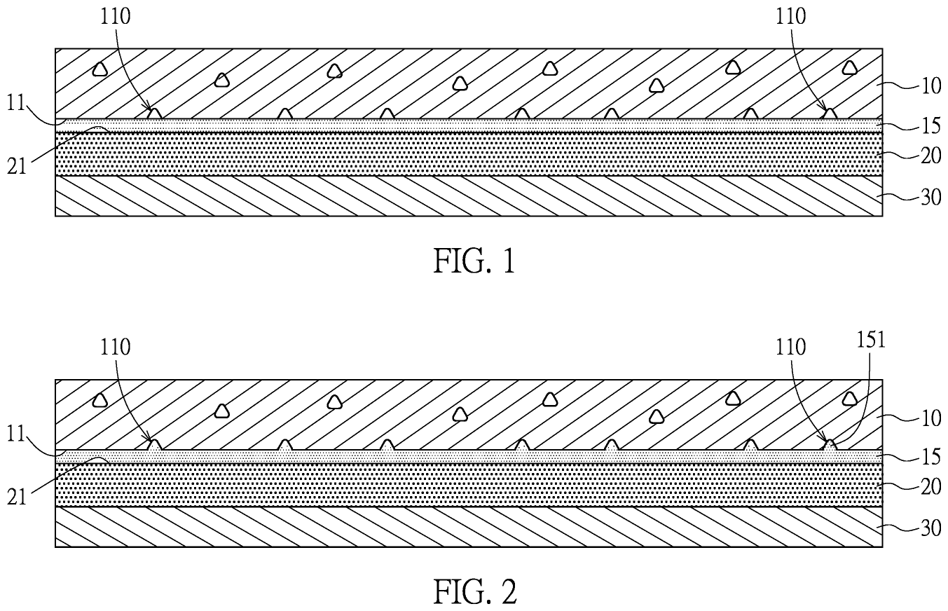

Reference is made to FIG. 1, which illustrates an immersion heat dissipation structure according to a first embodiment of the present disclosure. As shown in FIG. 1, the immersion heat dissipation structure provided by the first embodiment of the present disclosure includes, roughly from top to bottom, a porous metal heat dissipation material 10, a thermal interface material 20, and an integrated heat spreader 30.

In the present embodiment, the porous metal heat dissipation material 10 can be a porous copper heat dissipation material formed by sintering copper powder, and can be immersed in a two-phase coolant (such as an electronic fluorinated liquid), so that a number of air bubbles formed by evaporation of the two-phase coolant can be greatly increased, thereby greatly enhancing a heat dissipation effect. Moreover, the porous metal heat dissipation material 10 of the present embodiment has a porosity greater than 8%, such that the number of air bubbles formed by evaporation of the two-phase coolant can be greatly increased.

In the present embodiment, the integrated heat spreader 30 can be used to contact a heat-generating component, and the porous metal heat dissipation material 10 and the integrated heat spreader 30 have the thermal interface material 20 arranged therebetween, so that a thermal connection between the integrated heat spreader 30 and the porous metal heat dissipation material 10 is increased, thereby improving thermal transmittance from the integrated heat spreader 30 to the porous metal heat dissipation material 10.

In the present embodiment, the thermal interface material 20 can be made of silicone grease, silica gel, epoxy resin, or metal. Moreover, in order to enhance the thermal connection between the integrated heat spreader 30 and the porous metal heat spreader 10, so as to prevent a poor connection between the thermal interface material 20 and the porous metal heat dissipation material 10 occurring in the presence of tiny open pores, a connection surface 11 of the porous metal heat dissipation material 10 and a connection surface 21 of the thermal interface material 20 have a sealing layer 15 arranged therebetween. In addition, the sealing layer 15 is used to seal a plurality of open pores 110 formed on the connection surface 11 of the porous metal heat dissipation material 10, so that a connection property and a thermal conductivity between the thermal interface material 20 and the porous metal heat dissipation material 10 can be increased through the sealing layer 15, thereby further improving the thermal transmittance.

Furthermore, in the present embodiment, in order to further improve the connection property and the thermal transmittance between the thermal interface material 20 and the porous metal heat dissipation material 10 through the sealing layer 15, the sealing layer 15 is a film layer having a thickness of less than 0.1 mm. Moreover, the sealing layer 15 can be formed by one of a steaming process, blocking with an organosilicon compound, filling with a passivation solution, blocking with an immobilization material, a physical vapor deposition process, or a chemical vapor deposition process.

It should be noted that that the open pores are exaggeratedly enlarged in FIG. 1 for a better understanding of the present disclosure.

### Second Embodiment

Reference is made to FIG. 2, which illustrates an immersion heat dissipation structure according to a second embodiment of the present disclosure. The immersion heat dissipation structure of the second embodiment is substantially the same as that of the first embodiment, and differences therebetween are described below.

In the present embodiment, in order to enhance the thermal transmittance from the integrated heat spreader 30 to the porous metal heat dissipation material 10, the connection surface 11 of the porous metal heat dissipation material 10 and the connection surface 21 of the thermal interface material 20 have the sealing layer 15 arranged therebetween. Moreover, a sealing material 151 forming the sealing layer 15 is filled in at least one of the plurality of open pores 110 formed on the connection surface 11 of the porous metal heat dissipation material 10, so that the connection property and the thermal conductivity between the thermal interface material 20 and the porous metal heat dissipation material 10 can be increased through the sealing layer 15, thereby further improving the thermal transmittance.

### Third Embodiment

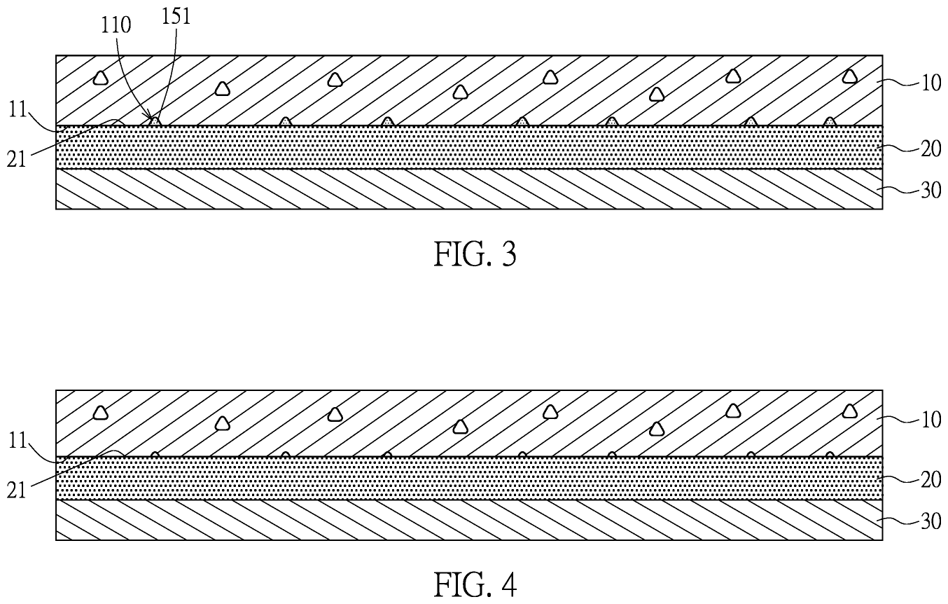

Reference is made to FIG. 3, which illustrates an immersion heat dissipation structure according to a third embodiment of the present disclosure. The immersion heat dissipation structure of the third embodiment is substantially the same as that of the first embodiment, and differences therebetween are described below.

In the present embodiment, in order to enhance the thermal connection between the integrated heat spreader 30 and the porous metal heat dissipation material 10, at least one of the plurality of open pores 110 formed on the connection surface 110 of the porous metal heat dissipation material 10 is filled with the sealing material 151 to fill at least a part of the at least one of the plurality of open pores 110. Moreover, the sealing material 151 is formed by forming the sealing layer 15 on the connection surface 11 of the porous metal heat dissipation material 10 (as shown in FIG. 2), removing the sealing layer 15 formed on the connection surface 11 by a chemical process or a mechanical process, and leaving a remaining part of the sealing material 151 of the sealing layer 15 in the open pore 110. Therefore, the connection property and the thermal conductivity between the thermal interface material 20 and the porous metal heat dissipation material 10 can be increased through the sealing material 151 left in the open pore 110, thereby further improving the thermal transmittance.

### Fourth Embodiment

Reference is made to FIG. 4, which illustrates an immersion heat dissipation structure according to a fourth embodiment of the present disclosure. The immersion heat dissipation structure of the fourth embodiment is substantially the same as that of the first embodiment, and differences therebetween are described below.

In the present embodiment, in order to enhance the thermal connection between the integrated heat spreader 30 and the porous metal heat dissipation material 10, the connection surface 11 of the porous metal heat dissipation material 10 is a processed surface having a porosity less than 8% that is formed by processing. Therefore, the connection property and the thermal conductivity between the thermal interface material 20 and the porous metal heat dissipation material 10 can be increased through the processed surface having the porosity less than 8%, thereby further improving the thermal transmittance.

Moreover, in the present embodiment, the connection surface 11 of the porous metal heat dissipation material 10 can be the processed surface having the porosity less than 8% that is formed by mechanical processing, such as sandblasting, grinding, and polishing.

In addition, in the present embodiment, the connection surface 11 of the porous metal heat dissipation material 10 can be the processed surface having the porosity less than 8% that is formed by chemical etching or acid etching.

### Beneficial Effects of the Embodiments

In conclusion, in the immersion heat dissipation structure provided by the present disclosure, by virtue of “the porous metal heat dissipation material 10 having the porosity greater than 8%”, “the porous metal heat dissipation material 10 and the integrated heat spreader 30 having the thermal interface material 20 arranged therebetween so that the thermal connection is formed therebetween”, “the connection surface 11 of the porous metal heat dissipation material 10 and the connection surface 21 of the thermal interface material 20 having the sealing layer 15 arranged therebetween, the sealing layer 15 sealing the plurality of open pores 110 formed on the connection surface 11 of the porous metal heat dissipation material 10, and the thickness of the sealing layer being less than 0.1 mm”, “the at least one of the plurality of open pores 110 formed on the connection surface 11 of the porous metal heat dissipation material 10 being filled with the sealing material 151 to fill at least a part of the at least one of the plurality of open pores 110”, or “the connection surface 11 of the porous metal heat dissipation material 10 being the processed surface having the porosity less than 8% that is formed by processing,” an air bubble generation in an area of the porous metal heat dissipation material 10 of the immersion heat dissipation structure provided by the embodiments of the present disclosure can be effectively increased, and the connection property and the thermal conductivity between the thermal interface material 20 and the porous metal heat dissipation material 10 can be effectively increased, thereby further improving the thermal transmittance of the immersion heat dissipation structure.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An immersion heat dissipation structure, comprising:
a porous metal heat dissipation material having a porosity greater than 8%;
an integrated heat spreader; and
a thermal interface material;
wherein the porous metal heat dissipation material and the integrated heat spreader have the thermal interface material arranged therebetween so that a thermal connection is formed therebetween, and a connection surface of the porous metal heat dissipation material and a connection surface of the thermal interface material have a sealing layer arranged therebetween;
wherein the sealing layer seals a plurality of open pores formed on the connection surface of the porous metal heat dissipation material, and a thickness of the sealing layer is less than 0.1 mm.

2. The immersion heat dissipation structure according to claim 1, wherein the sealing layer is a film layer formed by one of a steaming process, blocking with an organosilicon compound, filling with a passivation solution, blocking with an immobilization material, a physical vapor deposition process, or a chemical vapor deposition process.

3. The immersion heat dissipation structure according to claim 1, wherein the thermal interface material is made of silicone grease, silica gel, epoxy resin, or metal.

4. An immersion heat dissipation structure, comprising:
a porous metal heat dissipation material having a porosity greater than 8%;
an integrated heat spreader; and
a thermal interface material;
wherein the porous metal heat dissipation material and the integrated heat spreader have the thermal interface material arranged therebetween so that a thermal connection is formed therebetween;
wherein a plurality of open pores are formed on a connection surface of the porous metal heat dissipation material, and at least one of the plurality of open pores is filled with a sealing material to fill at least a part of the at least one of the plurality of open pores.

5. The immersion heat dissipation structure according to claim 4, wherein the sealing material is formed by forming a sealing layer on the connection surface of the porous metal heat dissipation material, and filling the sealing material forming the sealing layer into the at least one of the plurality of open pores.

6. The immersion heat dissipation structure according to claim 5, wherein the sealing layer is a film layer formed by one of a steaming process, blocking with an organosilicon compound, filling with a passivation solution, blocking with an immobilization material, a physical vapor deposition process, or a chemical vapor deposition process.

7. The immersion heat dissipation structure according to claim 4, wherein the sealing material is formed by forming a sealing layer on the connection surface of the porous metal heat dissipation material, removing the sealing layer by a chemical process or a mechanical process, and leaving a remaining part of the sealing material of the sealing layer in the open pore.

8. The immersion heat dissipation structure according to claim 4, wherein the thermal interface material is made of silicone grease, silica gel, epoxy resin, or metal.

9. An immersion heat dissipation structure, comprising:
a porous metal heat dissipation material having a porosity greater than 8%;
an integrated heat spreader; and
a thermal interface material;
wherein the porous metal heat dissipation material and the integrated heat spreader have the thermal interface material arranged therebetween so that a thermal connection is formed therebetween, and a connection surface of the porous metal heat dissipation material is a processed surface having a porosity less than 8% that is formed by processing.

10. The immersion heat dissipation structure according to claim 9, wherein the connection surface of the porous metal heat dissipation material is the processed surface having the porosity less than 8% that is formed by sandblasting, grinding, or polishing.

11. The immersion heat dissipation structure according to claim 9, wherein the connection surface of the porous metal heat dissipation material is the processed surface having the porosity less than 8% that is formed by chemical etching or acid etching.

12. The immersion heat dissipation structure according to claim 9, wherein the thermal interface material is made of silicone grease, silica gel, epoxy resin, or metal.
